(19) United States
(12) Patent Application Publication
(10) Pub. No.: US 2015/0124203 A1
(43) Pub. Date: May 7, 2015

(54) DISPLAY DEVICE AND MANUFACTURING METHOD THEREOF

(71) Applicant: Samsung Display Co., Ltd., Yongin-City (KR)

(72) Inventors: Seong Gyu KWON, Suwon-si (KR); Woo Jae LEE, Yongin-si (KR); Seok-Joon HONG, Seongnam-si (KR)

(73) Assignee: Samsung Display Co., Ltd., Yongin-City (KR)

(21) Appl. No.: 14/268,867

(22) Filed: May 2, 2014

(30) Foreign Application Priority Data
Nov. 1, 2013 (KR) 10-2013-0132348

(51) Int. Cl. G02F 1/1343; H01L 27/12

(52) U.S. Cl. CPC G02F 1/134336; H01L 27/1259; H01L 27/124
USPC 349/106; 349/139; 438/158

(57) ABSTRACT

Provided are a display device and a manufacturing method thereof capable of preventing a short defect between electrodes. The display device includes a substrate, a common electrode formed on the substrate, a pixel electrode formed on the common electrode to be spaced apart from the common electrode with a microcavity therebetween, a roof layer formed on the pixel electrode, a liquid crystal layer filing the microcavity, and an encapsulation layer formed on the roof layer to seal the microcavity.

### CROSS-REFERENCE TO RELATED APPLICATION

This application claims priority to and the benefit of Korean Patent Application No. 10-2013-0132348 filed in the Korean Intellectual Property Office on Nov. 1, 2013, the entire contents of which are incorporated herein by reference.

### BACKGROUND

(a) Technical Field

The present application relates to a display device and a manufacturing method thereof, and more particularly, to a display device and a manufacturing method thereof capable of preventing a short defect between electrodes.

(b) Description of the Related Art

A liquid crystal display, which is one of the most common types of flat panel displays currently in use, includes two sheets of display panels with field generating electrodes such as a pixel electrode and a common electrode, and a liquid crystal layer interposed therebetween. The liquid crystal display generates an electric field in the liquid crystal layer by applying a voltage to the field generating electrodes, determines alignment of liquid crystal molecules of the liquid crystal layer through the generated electric field and controls polarization of incident light, thereby displaying images.

Two sheets of display panels configuring the liquid crystal display may include a thin film transistor array panel and an opposing display panel. In the thin film transistor array panel, a gate line transferring a gate signal and a data line transferring a data signal are formed to cross each other, and a thin film transistor connected with the gate line and the data line, a pixel electrode connected with the thin film transistor, and the like may be formed. In the opposing display panel, a light blocking member, a color filter, a common electrode, and the like may be formed. In some cases, the light blocking member, the color filter, and the common electrode may be formed on the thin film transistor array panel.

However, in a liquid crystal display in the related art, two sheets of substrates are necessarily used, and respective constituent elements are formed on the two sheets of substrates, and as a result, there are problems in that the display device is heavy and thick, has high cost, and has a long processing time.

The above information disclosed in this Background section is only for enhancement of understanding of the background and therefore it may contain information that does not form the prior art that is already known in this country to a person of ordinary skill in the art.

### SUMMARY

Embodiments have been made in an effort to provide a display device and a manufacturing method thereof having advantages of reducing a weight, a thickness, cost, and a processing time by manufacturing the display device by using one substrate.

Further, embodiments have been made in an effort to provide a display device and a manufacturing method thereof having advantages of preventing a short defect between electrodes.

An exemplary embodiment provides a display device, including a substrate, a common electrode, a pixel electrode, a roof layer, a liquid crystal layer, and an encapsulation layer. The common electrode is formed on the substrate. The pixel electrode is formed on the common electrode to be spaced apart from the common electrode with a microcavity therebetween. The roof layer is formed on the pixel electrode. The liquid crystal layer fills the microcavity. The encapsulation layer is formed on the roof layer to seal the microcavity.

The display device may further include: a thin film transistor formed on the common electrode; and a connection electrode connecting the thin film transistor and the pixel electrode.

The pixel electrode may be formed to cover an upper surface of the microcavity.

The pixel electrode may be formed not to cover a side surface of the microcavity.

The microcavity may not be positioned on the thin film transistor, and the connection electrode may be formed to pass through a part of the side surface of the microcavity.

The substrate may include a plurality of pixel areas, the common electrode may be formed on the entire surface of the substrate, and the pixel electrode may be formed in the pixel area.

The pixel electrode may include a horizontal stem and a vertical stem crossing each other, and a minute branch extending from the horizontal stem and the vertical stem.

The display device may further include a gate line and a data line formed on the common electrode, in which the gate line and the data line may be connected with the thin film transistor.

The common electrode may include openings formed at portions overlapping with the gate line and the data line.

The display device may further include a color filter formed below the common electrode, in which the color filter may be formed in the pixel area.

Another exemplary embodiment provides a manufacturing method of a display device as follows. A common electrode is formed on a substrate. A sacrificial layer is formed on the common electrode. A pixel electrode is formed on the sacrificial layer. A roof layer is formed on the pixel electrode. An injection hole is formed by patterning the roof layer so that a part of the sacrificial layer is exposed. A microcavity is formed between the common electrode and the pixel electrode by removing the sacrificial layer. A liquid crystal layer is formed in the microcavity by injecting a liquid crystal material through the injection hole. An encapsulation layer is formed on the roof layer to seal the microcavity.

The manufacturing method of a display device may further include forming a thin film transistor on the common electrode.

In the forming of the pixel electrode, a connection electrode connecting the thin film transistor and the pixel electrode may be further formed.

The pixel electrode may be formed to cover an upper surface of the sacrificial layer and not to cover a side surface of the sacrificial layer.

The connection electrode may be formed to pass through a part of the side surface of the sacrificial layer.

The substrate may include a plurality of pixel areas, the common electrode may be formed on the entire surface of the substrate, and the pixel electrode may be formed in the pixel area.

A horizontal stem and a vertical stem crossing each other, and a minute branch extending from the horizontal stem and the vertical stem may be formed by patterning the pixel electrode.

The forming of the thin film transistor may include forming a gate line connected to the thin film transistor, and forming a data line connected with the thin film transistor.

The manufacturing method of a display device may further include forming openings by patterning the common electrode to remove at least a part of the portions overlapping with the gate line and the data line.

The manufacturing method of a display device may further include forming a color filter in the pixel area on the substrate, in which the color filter may be positioned below the common electrode.

As described above, the display device and the manufacturing method thereof according to the exemplary embodiments have the following effects.

In the display device and the manufacturing method thereof according to the exemplary embodiments, it is possible to reduce a weight, a thickness, cost, and a processing time by manufacturing the display device by using one substrate.

Further, it is possible to prevent a short defect between two electrodes, by forming a common electrode below a microcavity and forming a pixel electrode on the microcavity.

Further, it is possible to prevent an electric field between two electrodes from being distorted.

### BRIEF DESCRIPTION OF THE DRAWINGS

FIG. 1 is a plan view illustrating a display device according to an exemplary embodiment.

FIG. 2 is an equivalent circuit diagram of one pixel of the display device according to the exemplary embodiment.

FIG. 3 is a layout view illustrating one pixel of the display device according to the exemplary embodiment.

FIG. 4 is a cross-sectional view illustrating one pixel of the display device taken along line IV-IV of FIG. 3 according to the exemplary embodiment.

FIGS. 5, 6, 7, 8, 9, 10, 11, 12 are process cross-sectional views illustrating a manufacturing method of a display device according to an exemplary embodiment.

FIG. 13 is a layout view illustrating one pixel of a display device according to an exemplary embodiment.

FIG. 14 is a cross-sectional view illustrating one pixel of the display device taken along line XIV-XIV of FIG. 13 according to the exemplary embodiment.

### DETAILED DESCRIPTION OF THE EMBODIMENTS

The inventive concept will be described more fully hereinafter with reference to the accompanying drawings, in which exemplary embodiments are shown. As those skilled in the art would realize, the described embodiments may be modified in various different ways, all without departing from the spirit or scope of the inventive concept.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

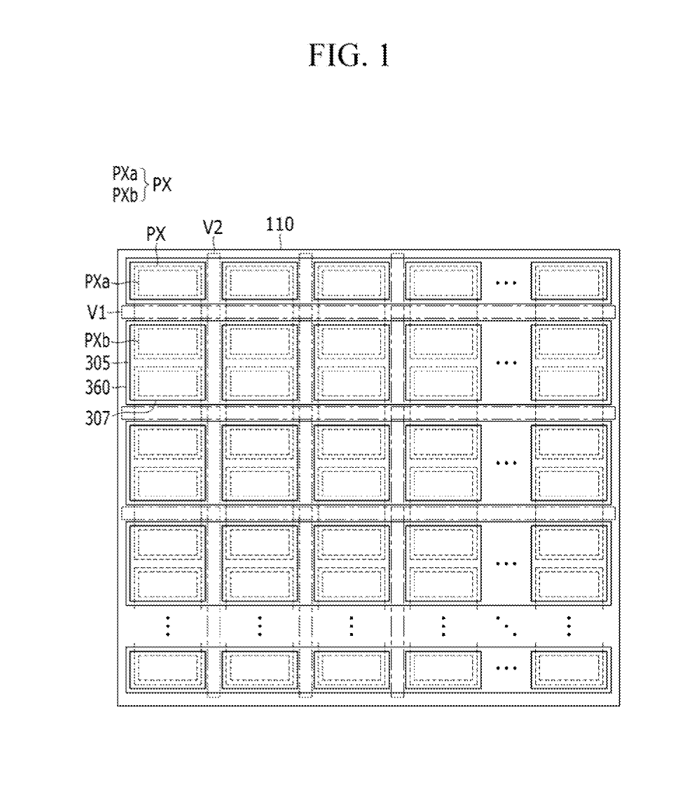

First, a display device according to an exemplary embodiment will be schematically described below with reference to FIG. 1.

FIG. 1 is a plan view illustrating a display device according to an exemplary embodiment.

A display device according to the exemplary embodiment includes a substrate 110 made of a material such as glass or plastic.

The substrate 110 includes a plurality of pixel areas PX. The plurality of pixel areas PX is disposed in a matrix form which includes a plurality of pixel rows and a plurality of pixel columns. Each pixel area PX may include a first subpixel area PXa and a second subpixel area PXb. The first subpixel area PXa and the second subpixel area PXb may be vertically disposed.

A microcavity 305 covered by a roof layer 360 is formed on the substrate 110. The roof layers 360 are connected to each other in a row direction, and one roof layer 360 may form a plurality of microcavities 305.

A first valley V1 is positioned between the first subpixel area PXa and the second subpixel area PXb in a pixel row direction, and a second valley V2 is positioned between a plurality of pixel columns.

The plurality of roof layers 360 is separated from each other with the first valley V1 therebetween. The microcavity 305 is not covered by the roof layer 360, but may be exposed to the outside at a portion contacting the first valley V1. This is called a liquid crystal injection hole 307.

Each roof layer 360 is formed to be separated from the substrate 110 between the adjacent second valleys V2 so as to form the microcavity 305. Further, each roof layer 360 is formed to be attached to the substrate 110 at the second valley V2 so as to cover both side surfaces of the microcavity 305.

A structure of the display device according to the exemplary embodiment described above is just exemplified and may be variously modified. For example, a layout form of the pixel area PX, the first valley V1, and the second valley V2 may be modified, and the plurality of roof layers 360 may be connected to each other at the first valley V1, and a part of each roof layer 360 may be formed to be separated from the substrate 110 at the second valley V2 and thus the adjacent microcavities 305 may be connected to each other.

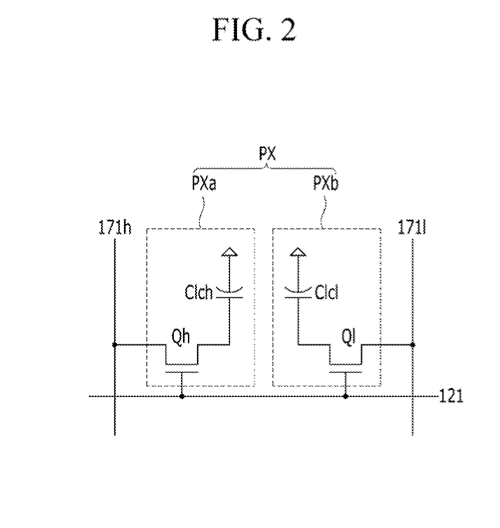

Hereinafter, one pixel of the display device according to the exemplary embodiment will be schematically described below with reference to FIG. 2.

FIG. 2 is an equivalent circuit diagram of one pixel of the display device according to the exemplary embodiment.

The display device according to the exemplary embodiment includes a plurality of signal lines 121, 171h, and 171l, and a plurality of pixels PX connected thereto.

The signal lines 121, 171h, and 171l include a gate line 121 transferring a gate signal, and a first data line 171h and a second data line 171l transferring different data voltages.

A first switching element Qh connected to the gate line 121 and the first data line 171h is formed, and a second switching element Ql connected to the gate line 121 and the second data line 171l is formed.

Each pixel PX includes two subpixels PXa and PXb, and in the first subpixel PXa, a first liquid crystal capacitor Clch connected to the first switching element Qh is formed, and in the second subpixel PXb, a second liquid crystal capacitor Clcl connected to the second switching element Ql is formed.

A first terminal of the first switching element Qh is connected to the gate line 121, a second terminal thereof is connected to the first data line 171h, and a third terminal thereof is connected to the first liquid crystal capacitor Clch.

A first terminal of the second switching element Ql is connected to the gate line 121, a second terminal thereof is connected to the second data line 171l, and a third terminal thereof is connected to the second liquid crystal capacitor Clcl.

In an operation of a liquid crystal display according to the exemplary embodiment, when a gate-on voltage is applied to the gate line 121, the first switching element Qh and the second switching element Ql connected thereto are turned on, and the first and second liquid crystal capacitors Clch and Clcl are charged by different data voltages transferred through the first and second data lines 171h and 171l. The data voltage transferred by the second data line 171l is lower than the data voltage transferred by the first data line 171h. Accordingly, the second liquid crystal capacitor Clcl is charged with a voltage lower than the first liquid crystal capacitor Clch, thereby improving side visibility.

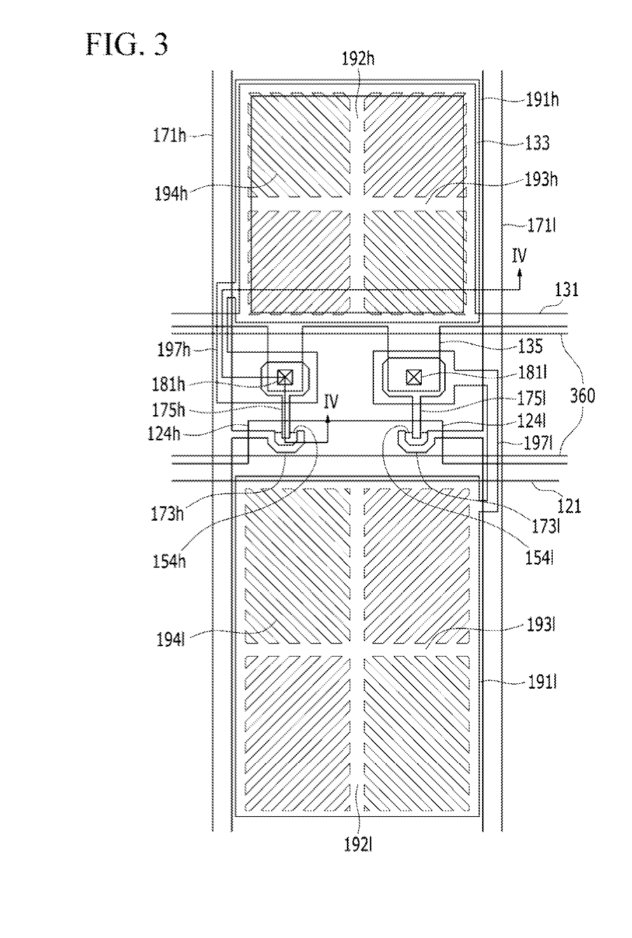

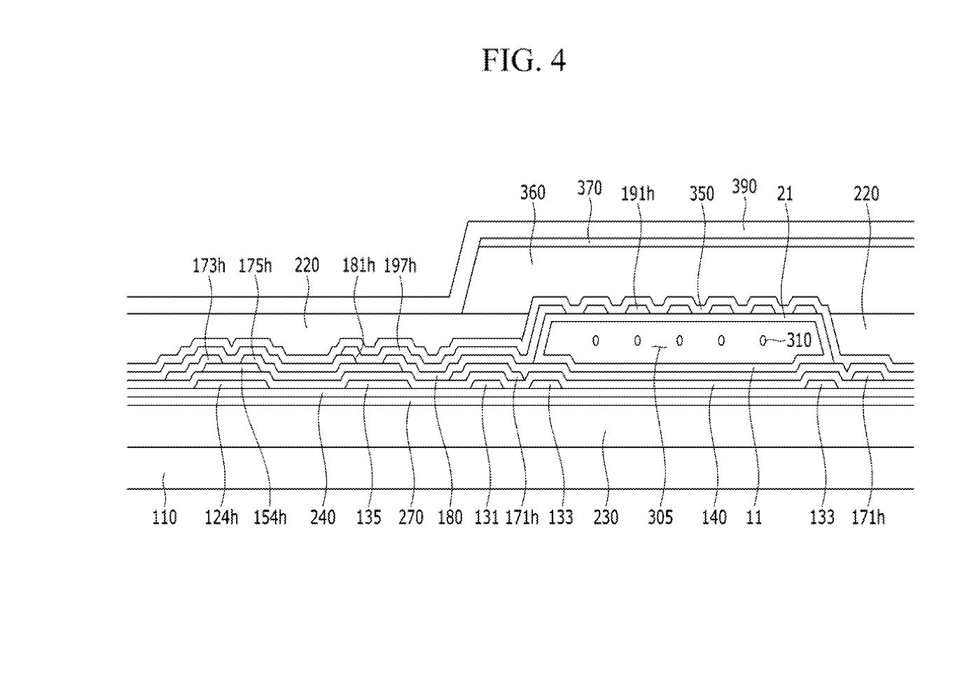

Hereinafter, a structure of one pixel of a liquid crystal display according to an exemplary embodiment will be described with reference to FIGS. 3 and 4.

FIG. 3 is a layout view illustrating one pixel of the display device according to the exemplary embodiment, and FIG. 4 is a cross-sectional view illustrating one pixel of the display device taken along line IV-IV of FIG. 3 according to the exemplary embodiment.

As illustrated in FIGS. 3 and 4, the display device according to an exemplary embodiment includes a common electrode 270 formed on the insulation substrate 110.

The common electrode 270 may be formed on the entire surface of the substrate 110. The common electrode 270 may be made of a transparent metal material such as indium tin oxide (ITO) and indium zinc oxide (IZO). A predetermined voltage may be applied to the common electrode 270.

A color filter 230 may be further formed between the substrate 110 and the common electrode 270. The color filter 230 may be formed in each pixel area PX. Further, the color filter 230 is not limited thereto, and may be formed to elongate in a column direction along a space between the first data line 171h and the second data line 171l. Each color filter 230 may display one of the primary colors such as three primary colors of red, green and blue. The color filter 230 is not limited to the three primary colors of red, green and blue, but may display cyan, magenta, yellow, and white-based colors, and the like.

A first insulating layer 240 is formed on the common electrode 270. The first insulating layer 240 may be made of an inorganic insulating material such as silicon nitride (SiNx) and silicon oxide (SiOx).

A gate line 121, and a first gate electrode 124h and a second gate electrode 124l which protrude from the gate line 121 are formed on the first insulating layer 240.

The gate line 121 extends mainly in a horizontal direction and transfers a gate signal. The first gate electrode 124h and the second gate electrode 124l protrude above the gate line 121. The first gate electrode 124h and the second gate electrode 124l are connected with each other to form one protrusion. However, embodiments are not limited thereto, and the protruding form of the first gate electrode 124h and the second gate electrode 124l may be variously modified.

A storage electrode line 131, and storage electrodes 133 and 135 protruding from the storage electrode line 131 may be further formed on the first insulating layer 240.

The storage electrode line 131 extends in the same direction as the gate line 121, and is formed to be spaced apart from the gate line 121. A predetermined voltage may be applied to the storage electrode line 131. The storage electrode 133 protruding above the storage electrode line 131 is formed to surround an edge of the first subpixel area PXa. The storage electrode 135 protruding below the storage electrode line 131 is formed to be adjacent to the first gate electrode 124h and the second gate electrode 124l.

A gate insulating layer 140 is formed on the gate line 121, the first gate electrode 124h, the second gate electrode 124l, the storage electrode line 131, and the storage electrodes 133 and 135. The gate insulating layer 140 may be made of an inorganic insulating material such as silicon nitride (SiNx) and silicon oxide (SiOx). Further, the gate insulating layer 140 may be constituted by a single layer or a multiple layer.

A first semiconductor 154h and a second semiconductor 154l are formed on the gate insulating layer 140. The first semiconductor 154h may be positioned on the first gate electrode 124h, and the second semiconductor 154l may be positioned on the second gate electrode 124l. The first semiconductor 154h may be formed to be extended below the first data line 171h, and the second semiconductor 154l may be formed to be extended below the second data line 171l. The first semiconductor 154h and the second semiconductor 154l may be made of amorphous silicon, polycrystalline silicon, metal oxide, and the like.

An ohmic contact member (not illustrated) may be further formed on each of the first semiconductor 154h and the second semiconductor 154l. The ohmic contact member may be made of silicide or a material such as n+ hydrogenated amorphous silicon in which an n-type impurity is doped at high concentration.

The first data line 171h, the second data line 171l, a first source electrode 173h, a first drain electrode 175h, a second source electrode 173l, and a second drain electrode 175l are formed on the first semiconductor 154h, the second semiconductor 154l, and the gate insulating layer 140.

The first data line 171h and the second data line 171l transfer data signals and mainly extend in a vertical direction to cross the gate line 121 and the storage electrode line 131. The first data line 171h and the second data line 171l transfer different data voltages. The data voltage transferred by the second data line 171l is lower than the data voltage transferred by the first data line 171h.

The first source electrode 173h is formed to protrude above the first gate electrode 124h from the first data line 171h, and the second source electrode 173l is formed to protrude above the second gate electrode 124l from the second data line 171l. Each of the first drain electrode 175h and the second drain electrode 175l includes one wide end portion and the other rod-shaped end portion. The wide end portions of the first drain electrode 175h and the second drain electrode 175l overlap with the storage electrode 135 protruding below the storage electrode line 131. The rod-shaped end portions of the first drain electrode 175h and the second drain electrode 175l are partially surrounded by the first source electrode 173h and the second source electrode 173l, respectively.

The first and second gate electrodes 124h and 124l, the first and second source electrodes 173h and 173l, and the first and second drain electrodes 175h and 175l form first and second thin film transistors (TFTs) Qh and Ql together with the first and second semiconductors 154h and 154l, respectively, and a channel of the thin film transistor is formed in each of the semiconductors 154h and 154l between each of the source electrodes 173h and 173l and each of the drain electrodes 175h and 175l.

A passivation layer 180 is formed on the first data line 171h, the second data line 171l, the first source electrode 173h, the first drain electrode 175h, the first semiconductor 154h exposed between the first source electrode 173h and the first drain electrode 175h, the second source electrode 173l, the second drain electrode 175l, and the second semiconductor 154l exposed between the second source electrode 173l and the second drain electrode 175l. The passivation layer 180 may be made of an organic insulating material or an inorganic insulating material, and may be formed in a single layer or a multiple layer.

In the passivation layer 180, a first contact hole 181h extending to and exposing the wide end portion of the first drain electrode 175h is formed, and a second contact hole 181l exposing the wide end portion of the second drain electrode 175l is formed.

A pixel electrode 191 is formed on the passivation layer 180 so as to be spaced apart from the common electrode 270 at a predetermined distance. A microcavity 305 is formed between the common electrode 270 and the pixel electrode 191. A width and an area of the microcavity 305 may be variously modified according to a size and resolution of the display device.

The pixel electrode 191 may be made of a transparent metal material such as indium tin oxide (ITO) and indium zinc oxide (IZO).

The pixel electrode 191 includes a first subpixel electrode 191h and a second subpixel electrode 191l which are separated from each other with the gate line 121 and the storage electrode line 131 therebetween, and disposed above and below the pixel area PX based on the gate line 121 and the storage electrode line 131 to be adjacent to each other in a column direction. That is, the first subpixel electrode 191h and the second subpixel electrode 191l are separated from each other with the first valley V1 therebetween, the first subpixel electrode 191h is positioned in the first subpixel area PXa, and the second subpixel electrode 191l is positioned in the second subpixel area PXb.

An overall shape of the first subpixel electrode 191h and the second subpixel electrode 191l is a quadrangle, and the first subpixel electrode 191h and the second subpixel electrode 191l include cross stems including horizontal 193h and 193l and vertical stems 192h and 192l crossing the horizontal stems 193h and 193l, respectively. Further, the first subpixel electrode 191h and the second subpixel electrode 191l include a plurality of minute branches 194h and 194l, respectively.

The pixel electrode 191 is divided into four subregions by the horizontal stems 193h and 193l and the vertical stems 192h and 192l. The minute branches 194h and 194l obliquely extend from the horizontal stems 193h and 193l and the vertical stems 192h and 192l, and the extending direction may form an angle of approximately 45 degrees or 135 degrees with the gate line 121 or the horizontal stems 193h and 193l. Further, directions in which the minute branches 194h and 194l of the two adjacent subregions extend may be orthogonal to each other.

In the exemplary embodiment, the first subpixel electrode 191h and the second subpixel electrode 191l may further include outer stems surrounding outsides of the first subpixel electrode 191h and the second subpixel electrode 191l.

A first connection electrode 197h and a second connection electrode 197l, which are connected to the first subpixel electrode 191h and the second subpixel electrode 191l, respectively, are formed on the passivation layer 180. The first subpixel electrode 191h and the second subpixel electrode 191l are formed so as to cover an upper surface of the microcavity 305, but so as not to cover the side surface of the microcavity 305. The first connection electrode 197h and the second connection electrode 197l are formed to pass through a part of the side surface of the microcavity 305. The microcavity 305 is not positioned on the first and second thin film transistors Qh and Ql. The first and second connection electrodes 197h and 197l serve to connect the first and second subpixel electrodes 191h and 191l positioned on the upper surface of the microcavity 305 with the first and second thin film transistors Qh and Ql positioned outside the microcavity 305, respectively.

The first connection electrode 197h and the second connection electrode 197l are connected to the first drain electrode 175h and the second drain electrode 175l through the first contact hole 181h and the second contact hole 181l, respectively. Accordingly, when the first thin film transistor Qh and the second thin film transistor Ql are turned on, the first subpixel electrode 191h and the second subpixel electrode 191l receive different data voltages from the first drain electrode 175h and the second drain electrode 175l. An electric field may be generated between the pixel electrode 191 and the common electrode 270.

The first connection electrode 197h and the second connection electrode 197l may be made of the same material as the first subpixel electrode 191h and the second subpixel electrode 191l.

In the exemplary embodiment, the common electrode 270 is formed below the microcavity 305, and the pixel electrode 191 is formed on the microcavity 305 so as not to cover the side surface of the microcavity 305, thereby preventing a short between the two electrodes from being generated. A vertical electric field may be generated between the common electrode 270 and the pixel electrode 191. In this case, the pixel electrode 191 is not positioned on the side surface of the microcavity 305, thereby preventing the electric field from being distorted.

The layout form of the pixel area, the structure of the thin film transistor, and the shape of the pixel electrode, which are described above, are just exemplified, and embodiments are not limited thereto and may be variously modified.

A first alignment layer 11 is formed on the passivation layer 180 inside the microcavity 305. A second alignment layer 21 is formed below the pixel electrode 191 to face the first alignment layer 11.

The first alignment layer 11 and the second alignment layer 21 may be formed by a vertical alignment layer, and made of an alignment material such as polyamic acid, polysiloxane, and polyimide. The first and second alignment layers 11 and 21 may be formed even on a side wall of the microcavity 305 and connected to each other.

A liquid crystal layer constituted by liquid crystal molecules 310 is formed in the microcavity 305 positioned between the common electrode 270 and the pixel electrode 191. The liquid crystal molecules 310 have negative dielectric anisotropy, and may stand up in a vertical direction to the substrate 110 while the electric field is not applied. That is, vertical alignment may be made.

The first subpixel electrode 191h and the second subpixel electrode 191l to which the data voltage is applied generate an electric field together with the common electrode 270 to determine directions of the liquid crystal molecules 310 positioned in the microcavity 305 between the two electrodes 191 and 270. As such, luminance of light passing through the liquid crystal layer varies according to the determined directions of the liquid crystal molecules 310.

A second insulating layer 350 may be further formed on the pixel electrode 191. The second insulating layer 350 may be made of an inorganic insulating material such as silicon nitride (SiNx) and silicon oxide (SiOx), and may be omitted if necessary.

A light blocking member 220 is formed on the second insulating layer 350. The light blocking member 220 is formed on a boundary of the pixel area PX and the thin film transistor, and may be formed at the first valley V1 positioned between the first subpixel area PXa and the second subpixel area PXb. The light blocking member 220 serves to block light leakage.

The roof layer 360 is formed on the light blocking member 220 and the second insulating layer 350. The roof layer 360 may be made of an organic material. The microcavity 305 is formed below the roof layer 360, and the roof layer 360 is hardened by a curing process to maintain the shape of the microcavity 305.

The roof layer 360 is formed in each pixel area PX along a pixel row and the second valley V2, and is not formed at the first valley V1. That is, the roof layer 360 is not formed between the first subpixel area PXa and the second subpixel area PXb. The microcavity 305 is formed below each roof layer 360 in each of the first subpixel area PXa and the second subpixel area PXb. In the second valley V2, the microcavity 305 is not formed below the roof layer 360, but the roof layer 360 is formed to be attached to the substrate 110. Accordingly, a thickness of the roof layer 360 positioned at the second valley V2 may be larger than a thickness of the roof layer 360 positioned in each of the first subpixel area PXa and the second subpixel area PXb. The upper surface and both side surfaces of the microcavity 305 have a form to be covered by the roof layer 360.

The injection hole 307 extending to and exposing a part of the microcavity 305 is formed in the roof layer 360. The injection holes 307 may be formed at edges of the first subpixel area PXa and the second subpixel area PXb, and formed to extend to and expose the side surface of the microcavity 305. Since the microcavity 305 is exposed by the injection hole 307, an aligning agent or a liquid crystal material may be injected into the microcavity 305 through the injection hole 307.

A third insulating layer 370 may be further formed on the roof layer 360. The third insulating layer 370 may be made of an inorganic insulating material such as silicon nitride (SiNx) and silicon oxide (SiOx). The third insulating layer 370 is formed to cover the upper surface of the roof layer 360. Further, embodiments are not limited thereto, and the third insulating layer 370 may be formed to cover the upper surface and the side surface of the roof layer 360. The third insulating layer 370 serves to protect the roof layer 360 made of an organic material, and may be omitted if necessary.

An encapsulation layer 390 may be formed on the third insulating layer 370. The encapsulation layer 390 is formed to cover the injection hole 307 through which the microcavity 305 is exposed to the outside. That is, the encapsulation layer 390 may seal the microcavity 305 so that the liquid crystal molecules 310 formed in the microcavity 305 are not discharged to the outside. Since the encapsulation layer 390 contacts the liquid crystal molecules 310, the encapsulation layer 390 may be made of a material which does not react with liquid crystal molecules 310. For example, the encapsulation layer 390 may be made of parylene and the like.

The encapsulation layer 390 may be formed by a multilayer such as a double layer and a triple layer. The double layer is configured by two layers made of different materials. The triple layer is configured by three layers, and materials of adjacent layers are different from each other. For example, the encapsulation layer 390 may include a layer made of an organic insulating material and a layer made of an inorganic insulating material.

Although not illustrated, polarizers may be further formed on upper and lower sides of the display device. The polarizers may be configured by a first polarizer and a second polarizer. The first polarizer may be attached onto the lower side of the substrate 110, and the second polarizer may be attached onto the encapsulation layer 390.

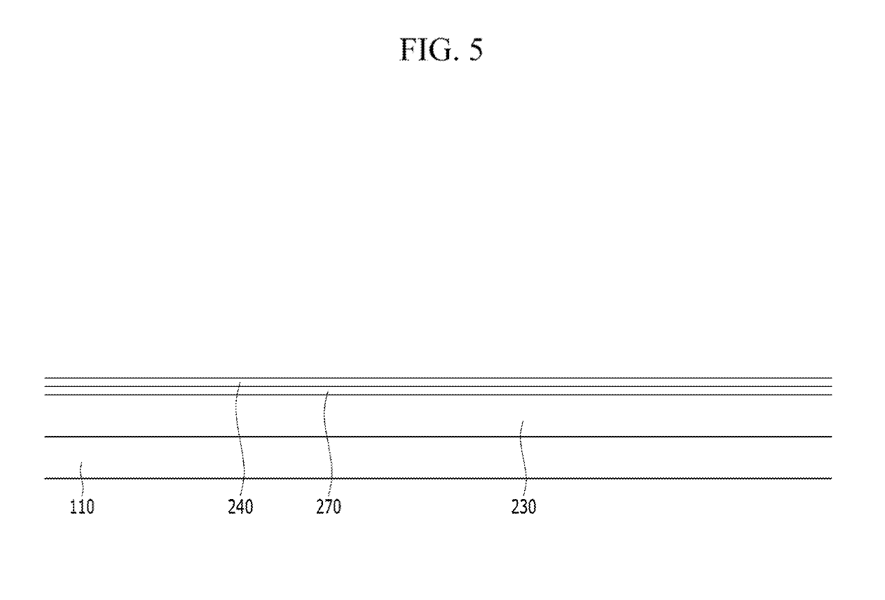

Next, a manufacturing method of a display device according to an exemplary embodiment will be described below with reference to FIGS. 5 to 12. Further, the manufacturing method will be described with reference to FIGS. 1 to 4 together.

FIGS. 5 to 12 are process cross-sectional views illustrating a manufacturing method of a display device according to an exemplary embodiment.

First, as illustrated in FIG. 5, a color filter 230 is formed on a substrate 110 made of glass, plastic, or the like. The color filter 230 may be formed in each pixel area PX, or formed to elongate in a column direction.

The color filters 230 having the same color may be formed in a column direction of the plurality of pixel areas PX. In the case of forming the color filters 230 having three colors, a first colored color filter 230 may be first formed, and then a second colored color filter 230 may be formed by shifting a mask. Next, the second colored color filter 230 may be formed, and then a third colored color filter may be formed by shifting a mask.

Next, a common electrode 270 is formed by depositing a transparent metal material such as indium tin oxide (ITO) and indium zinc oxide (IZO) on the color filter 230. The common electrode 270 may be formed on the entire surface of the substrate 110.

Next, a first insulating layer 240 is formed by depositing an inorganic insulating material such as silicon nitride (SiNx) and silicon oxide (SiOx) on the common electrode 270.

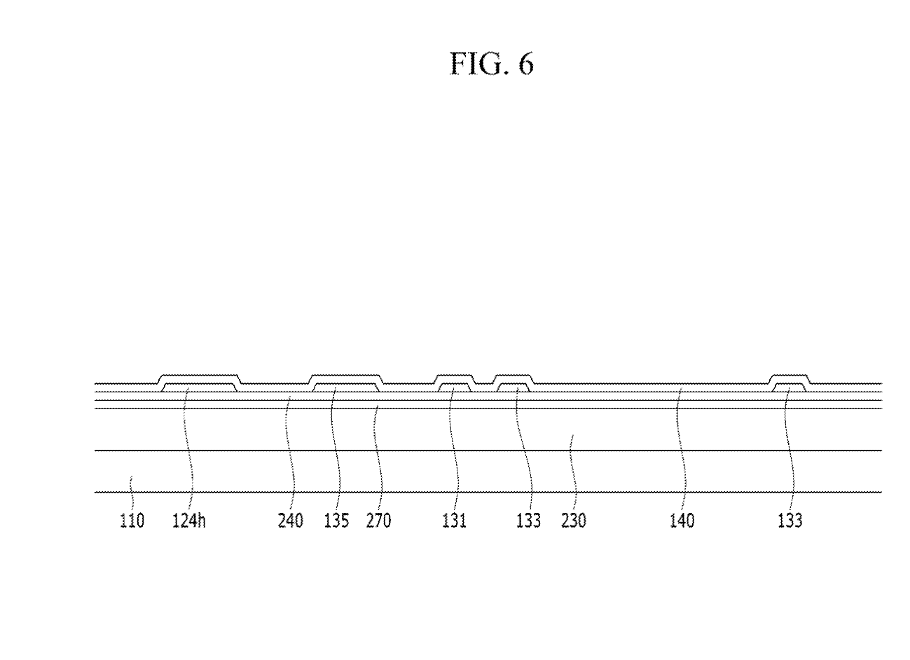

As illustrated in FIG. 6, a gate line 121 extending in one direction, and a first gate electrode 124h and a second gate electrode 124l protruding from the gate line 121 are formed on the first insulating layer 240. The first gate electrode 124h and the second gate electrode 124l are connected with each other to form one protrusion.

Further, a storage electrode line 131 and storage electrodes 133 and 135 protruding from the storage electrode line 131 may be formed together to be spaced apart from the gate line 121. The storage electrode line 131 extends in the same direction as the gate line 121. The storage electrode 133 protruding above the storage electrode line 131 may be formed to surround an edge of a first subpixel area PXa, and the storage electrode 135 protruding below the storage electrode line 131 may be formed to be adjacent to the first gate electrode 124h and the second gate electrode 124l.

Next, a gate insulating layer 140 is formed on the gate line 121, the first gate electrode 124h, the second gate electrode 124l, the storage electrode line 131, and the storage electrodes 133 and 135 by using an inorganic insulating material such as silicon oxide (SiOx) or silicon nitride (SiNx). The gate insulating layer 140 may be formed by a single layer or a multiple layer.

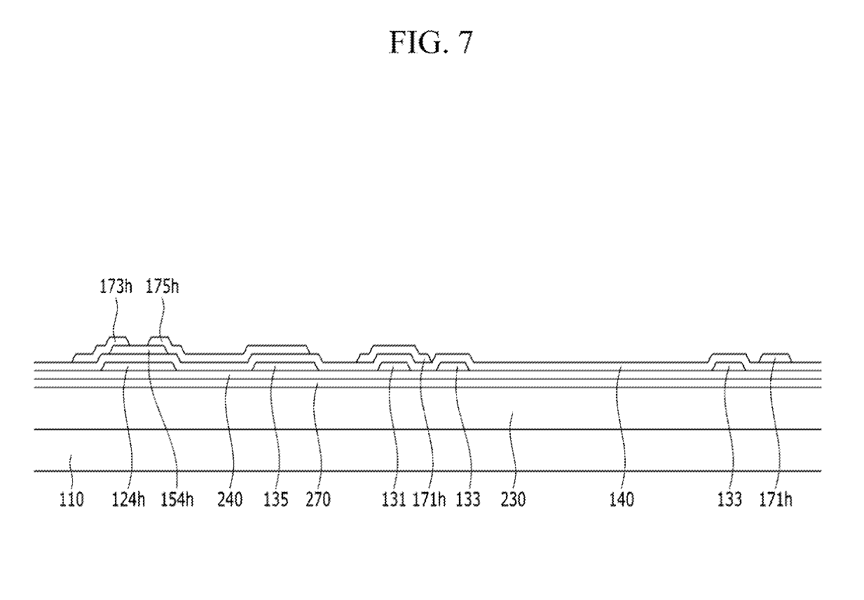

As illustrated in FIG. 7, a first semiconductor 154h and a second semiconductor 154l are formed by depositing and then patterning a semiconductor material such as amorphous silicon, polycrystalline silicon, and metal oxide on the gate insulating layer 140. The first semiconductor 154h may be formed to be positioned on the first gate electrode 124h, and the second semiconductor 154l may be formed to be positioned on the second gate electrode 124l.

Next, a first data line 171h and a second data line 171l extending in the other direction are formed by depositing and then patterning a metal material. The metal material may be formed by a single layer or a multiple layer.

Further, a first source electrode 173h protruding above the first gate electrode 124h from the first data line 171h, and a first drain electrode 175h spaced apart from the first source electrode 173h are formed together. Further, a second source electrode 173l connected with the first source electrode 173h, and a second drain electrode 175l spaced apart from the second source electrode 173l are formed together.

The first and second semiconductors 154h and 154l, the first and second data lines 171h and 171l, the first and second source electrodes 173h and 173l, and the first and second drain electrodes 175h and 175l may be formed by sequentially depositing and then simultaneously patterning a semiconductor material and a metal material. In this case, the first semiconductor 154h is formed to be extended below the first data line 171h, and the second semiconductor 154l is formed to be extended below the second data line 171l.

The first and second gate electrodes 124h and 124l, the first and second source electrodes 173h and 173l, and the first and second drain electrodes 175h and 175l form first and second thin film transistors (TFTs) Qh and Ql together with the first and second semiconductors 154h and 154l, respectively.

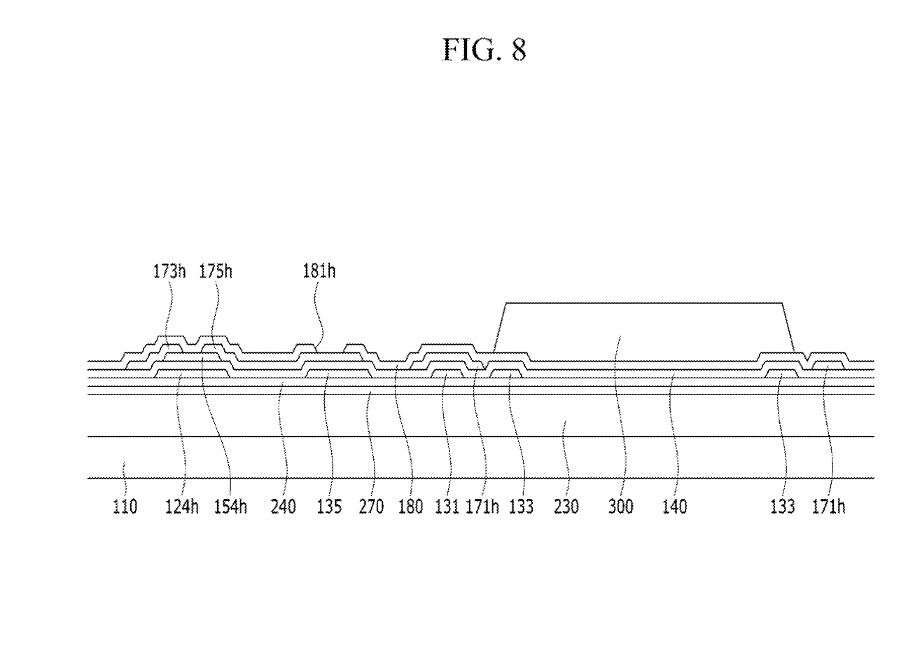

As illustrated in FIG. 8, a passivation layer 180 is formed on the first data line 171h, the second data line 171l, the first source electrode 173h, the first drain electrode 175h, the first semiconductor 154h exposed between the first source electrode 173h and the first drain electrode 175h, the second source electrode 173l, the second drain electrode 175l, and the second semiconductor 154l exposed between the second source electrode 173l and the second drain electrode 175l. The passivation layer 180 may be made of an organic insulating material or an inorganic insulating material, and may be formed in a single layer or a multiple layer.

Next, by patterning the passivation layer 180, a first contact hole 181h exposing at least a part of the first drain electrode 175h is formed, and a second contact hole 181l exposing at least a part of the second drain electrode 175l is formed.

Next, a sacrificial layer 300 is formed through a photolithography process by coating a photosensitive organic material on the passivation layer 180. The sacrificial layer 300 is formed to cover the pixel area PX, but formed not to cover at least a part of the first and second thin film transistors Qh and Ql.

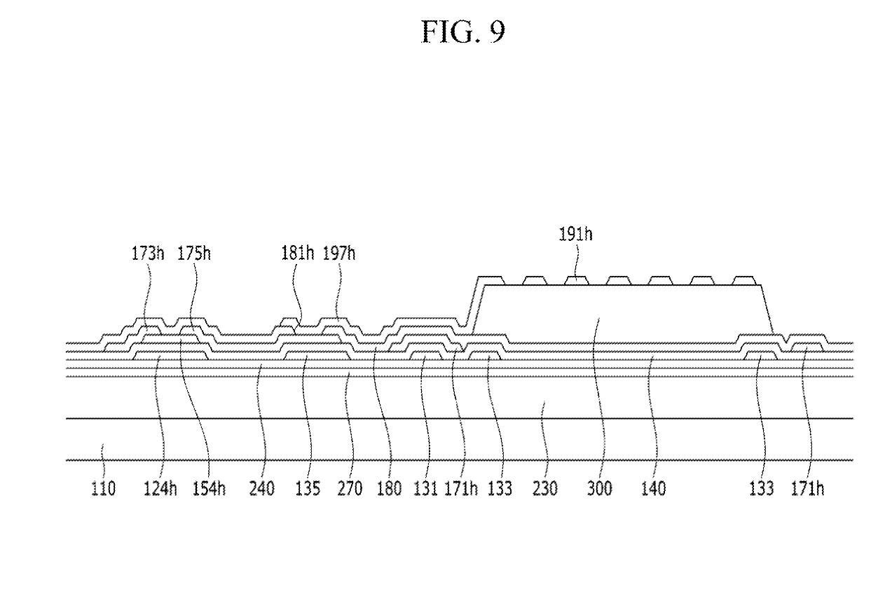

As illustrated in FIG. 9, a pixel electrode 191 is formed in the pixel area PX by depositing and patterning a transparent metal material such as indium tin oxide (ITO) and indium zinc oxide (IZO) on the sacrificial layer 300. The pixel electrode 191 includes a first subpixel electrode 191h positioned in the first subpixel area PXa, and a second subpixel electrode 191l positioned in the second subpixel area PXb. The first subpixel electrode 191h and the second subpixel electrode 191l are separated from each other with a first valley V1 therebetween.

Horizontal stems 193h and 193l, and vertical stems 192h and 192l crossing the horizontal stems 193h and 193l are formed in the first subpixel electrode 191h and the second subpixel electrode 191l, respectively. Further, a plurality of minute branches 194h and 194l, which obliquely extends from the horizontal stems 193h and 193l and the vertical stems 192h and 192l, is formed.

Further, a first connection electrode 197h and a second connection electrode 197l, which are connected to the first subpixel electrode 191h and the second subpixel electrode 191l, respectively, may be formed together. The first subpixel electrode 191h and the second subpixel electrode 191l are formed so as to cover an upper surface of the sacrificial layer 300, but so as not to cover the side surface of the sacrificial layer 300. The first connection electrode 197h and the second connection electrode 197l are formed to pass through a part of the side surface of a microcavity 305. The sacrificial layer 300 is not formed on the first and second thin film transistors Qh and Ql. The first and second connection electrodes 197h and 197l serve to connect the first and second subpixel electrodes 191h and 191l positioned on the upper surface of the sacrificial layer 300 with the first and second thin film transistors Qh and Ql which are not covered by the sacrificial layer 300.

The first connection electrode 197h and the second connection electrode 197l are formed to be connected to the first drain electrode 175h and the second drain electrode 175l through the first contact hole 181h and the second contact hole 181l, respectively.

The first connection electrode 197h and the second connection electrode 197l may be made of the same material as the first subpixel electrode 191h and the second subpixel electrode 191l through the same process.

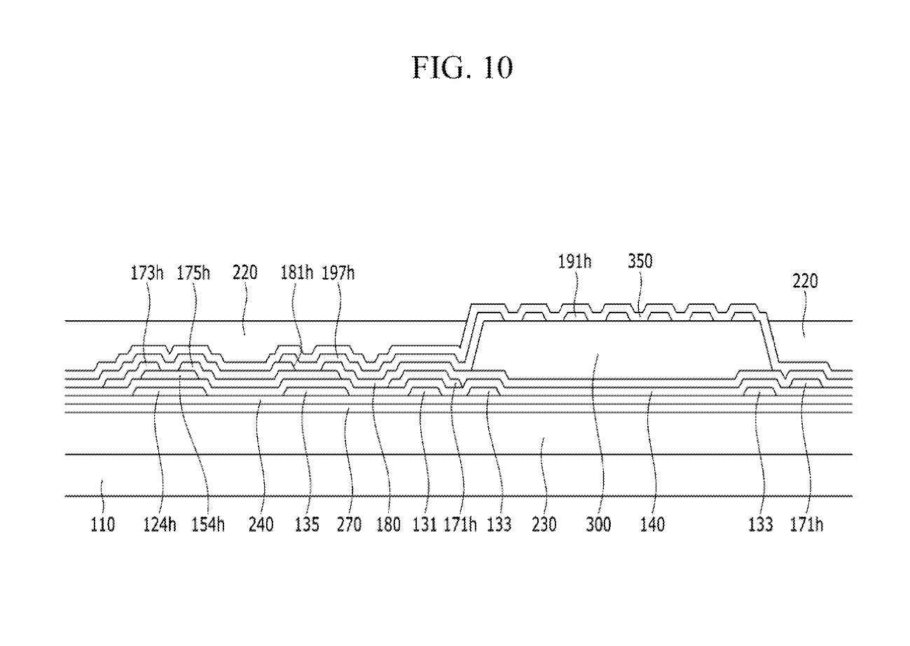

As illustrated in FIG. 10, a second insulating layer 350 is formed on the pixel electrode 191 by using an inorganic insulating material such as silicon nitride (SiNx) and silicon oxide (SiOx).

Next, a light blocking member 220 is formed on the second insulating layer 350. The light blocking member 220 is formed on a boundary of the pixel area PX and the thin film transistor, and may be formed at the first valley V1 positioned between the first subpixel area PXa and the second subpixel area PXb.

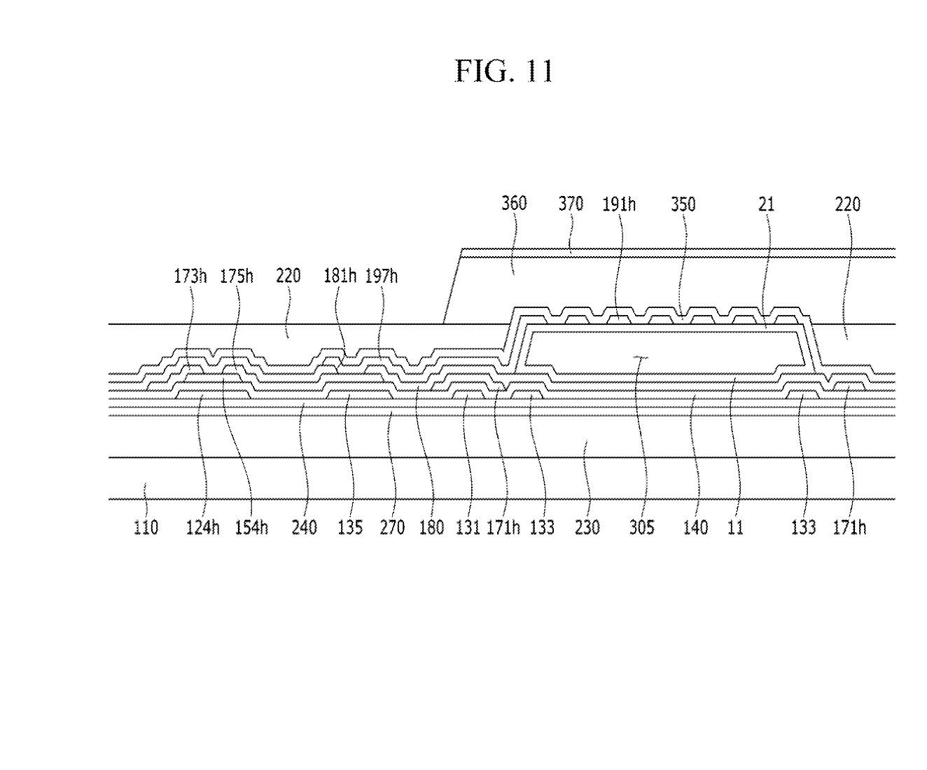

Next, as illustrated in FIG. 11, a roof layer 360 is formed by coating and patterning an organic material on the second insulating layer 350. In this case, the organic material positioned at the first valley V1 may be patterned so as to be removed. As a result, the roof layers 360 may be formed to be connected to each other along a plurality of pixel rows.

Next, a third insulating layer 370 may be formed on the roof layer 360 with an inorganic insulating material such as silicon nitride (SiNx) and silicon oxide (SiOx). The third insulating layer 370 positioned at the first valley V1 is removed by patterning the third insulating layer 370. In this case, as illustrated in the drawing, the third insulating layer 370 may be patterned so as not to be formed at the side surface of the roof layer 360. Unlike this, the third insulating layer 370 may be patterned to cover the side surface of the roof layer 360.

A part of the sacrificial layer 300 is exposed to the outside by patterning the roof layer 360 and the third insulating layer 370. The sacrificial layer 300 is fully removed by supplying a developer or a stripper solution on the substrate 110 where the sacrificial layer 300 is exposed, or the sacrificial layer 300 is fully removed by using an ashing process.

When the sacrificial layer 300 is removed, the microcavity 305 is generated at a site where the sacrificial layer 300 is positioned. The common electrode 270 and the pixel electrode 191 are spaced apart from each other with the microcavity 305 therebetween.

The side surface of the microcavity 305 is exposed to the outside through a portion where the roof layer 360 is removed, which is called an injection hole 307. The injection hole 307 may be formed along the first valley V1. For example, the injection hole 307 may be formed at the edges of the first subpixel area PXa and the second subpixel area PXb.

Next, the roof layer 360 is cured by applying heat to the substrate 110. This is to maintain the shape of the microcavity 305 by the roof layer 360.

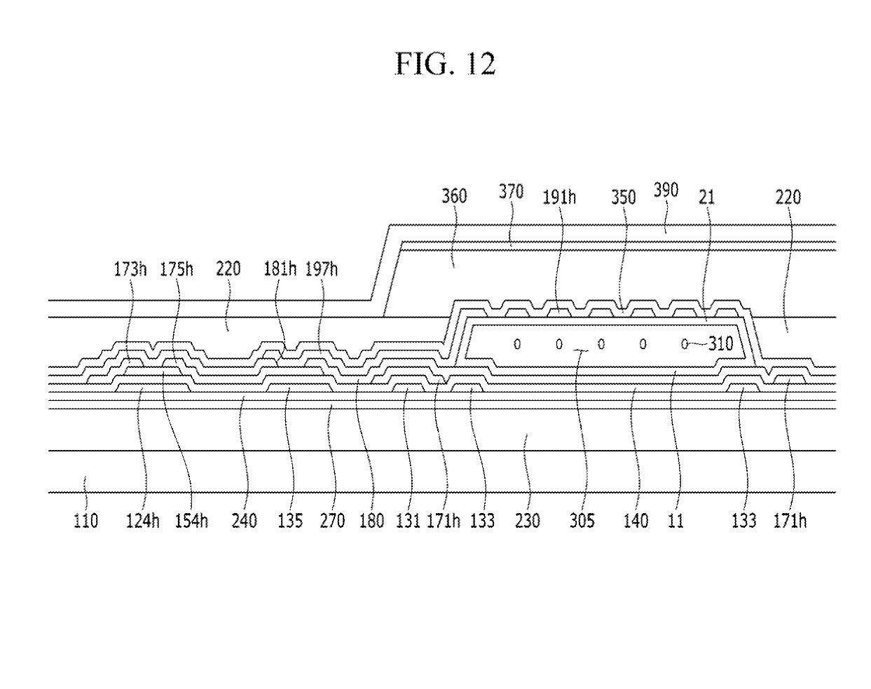

As illustrated in FIG. 12, when an aligning agent containing an alignment material is dropped on the substrate 110 by a spin coating method or an inkjet method, the aligning agent is injected into the microcavity 305 through the injection hole 307. When the aligning agent is injected into the microcavity 305 and then a curing process is performed, a solution component is evaporated and the alignment material remains on an inner wall of the microcavity 305.

Accordingly, a first alignment layer 11 may be formed on the common electrode 270, and a second alignment layer 21 may be formed below the pixel electrode 191. The first alignment layer 11 and the second alignment layer 21 may face each other with the microcavity 305 therebetween, and be connected to each other at the side wall of the microcavity 305.

In this case, the first and second alignment layers 11 and 21 may be aligned in a vertical direction to the substrate 110.

Next, when a liquid crystal material is dropped on the substrate 110 by an inkjet method or a dispensing method, the liquid crystal material is injected into the microcavity 305 through the injection hole 307. When the liquid crystal material is dropped, the liquid crystal material is injected into the microcavity 305 by capillary force.

Next, an encapsulation layer 390 is formed by depositing a material, which does not react with the liquid crystal molecules 310, on the third insulating layer 370. The encapsulation layer 390 is formed to cover the injection hole 307 through which the microcavity 305 is exposed to the outside, thereby sealing the microcavity 305.

Next, although not illustrated, polarizers may be further attached onto the upper and lower surfaces of the display device. The polarizers may be configured by a first polarizer and a second polarizer. The first polarizer may be attached onto the lower surface of the substrate 110, and the second polarizer may be attached onto the encapsulation layer 390.

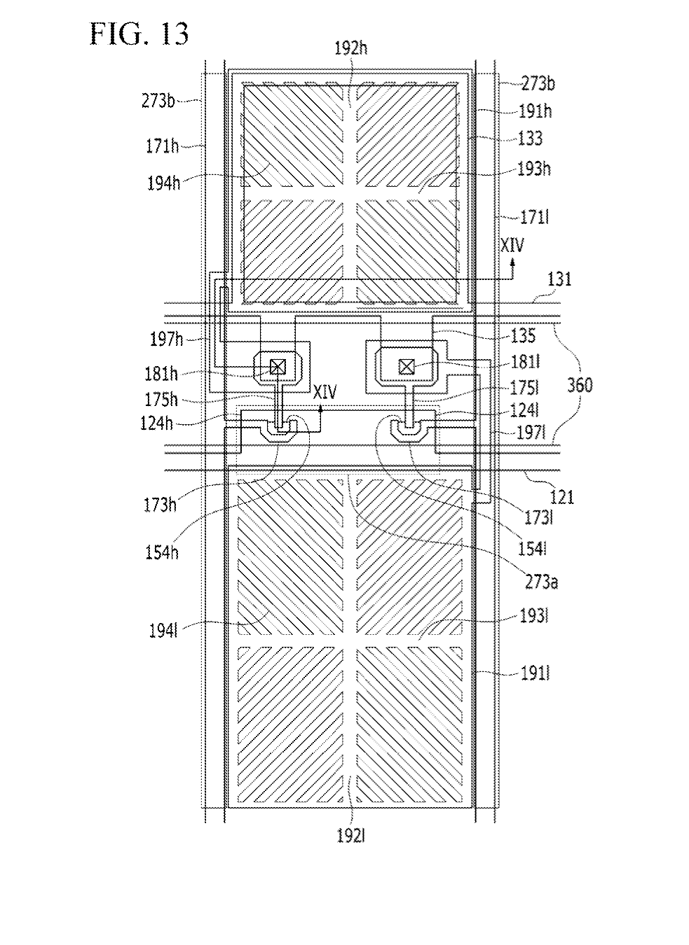

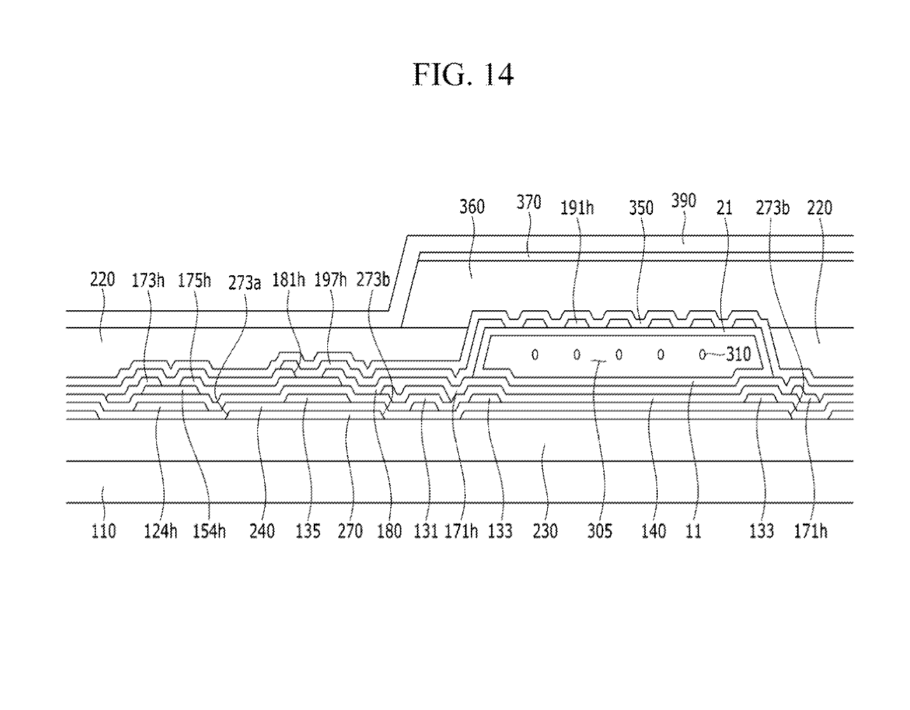

Next, a display device according to an exemplary embodiment will be described below with reference to FIGS. 13 and 14.

Since the display device according to an exemplary embodiment illustrated in FIGS. 13 and 14 is almost the same as the display device according to the exemplary embodiment illustrated in FIGS. 1 to 4, the description thereof is omitted. The exemplary embodiment is different from the above exemplary embodiment in that an opening is formed in the common electrode, and hereinafter, will be described in more detail.

FIG. 13 is a layout view illustrating one pixel of a display device according to an exemplary embodiment, and FIG. 14 is a cross-sectional view illustrating one pixel of the display device taken along line XIV-XIV of FIG. 13 according to the exemplary embodiment.

In the display device according to the exemplary embodiment, a common electrode 270 is formed on a substrate 110, and a pixel electrode 191 is formed on the substrate 110 with the common electrode 270 and a microcavity 305 therebetween.

The common electrode 270 is formed on most of the area of the substrate 110, but is removed at a partial region. That is, the common electrode 270 includes openings 273a and 273b. The common electrode 270 includes an opening 273a formed at a portion overlapping with a gate line 121, and an opening 273b formed at a portion overlapping with first and second data lines 171h and 171l.

A gate signal is applied to the gate line 121, and a data signal is applied to the first and second data lines 171h and 171l, and as a result, capacitance is generated at portions where the gate line 121, and the first and second data lines 171h and 171l overlap with the common electrode 270. In the exemplary embodiment, the common electrode 270 at the portions overlapping with the gate line 121 and the first and second data lines 171h and 171l is patterned to be removed to form the openings 273a and 273b, thereby reducing the capacitance.

While the inventive concept has been described in connection with what is presently considered to be practical exemplary embodiments, it is to be understood that the inventive concept is not limited to the disclosed embodiments, but, on the contrary, is intended to cover various modifications and equivalent arrangements included within the spirit and scope of the appended claims.

<Description of symbols>

| | |
|---|---|
| 11: First alignment layer | 21: Second alignment layer |
| 110: Substrate | 121: Gate line |
| 124h: First gate electrode | 124l: Second gate electrode |
| 131: Storage electrode line | 133, 135: Storage electrode |
| 140: Gate insulating layer | 154h: First semiconductor |
| 154l: Second semiconductor | 171h: First data line |
| 171l: Second data line | 173h: First source electrode |
| 173l: Second source electrode | 175h: First drain electrode |
| 175l: Second drain electrode | 180: Passivation layer |
| 181h: First contact hole | 181l: Second contact hole |
| 191h: First subpixel electrode | 191l: Second subpixel electrode |
| 220: Light blocking member | 230: Color filter |
| 240: First insulating layer | 270: Common electrode |
| 273a, 273b: Opening | 300: Sacrificial layer |
| 305: Microcavity | 307: Injection hole |
| 310: Liquid crystal molecule | 350: Second insulating layer |
| 360: Roof layer | 370: Third insulating layer |
| 390: Encapsulation layer | |

What is claimed is:

1. A display device, comprising:
a substrate;
a common electrode formed on the substrate;
a pixel electrode formed on the common electrode to be spaced apart from the common electrode with a microcavity therebetween;
a roof layer formed on the pixel electrode;
a liquid crystal layer filing the microcavity; and
an encapsulation layer formed on the roof layer to seal the microcavity.

2. The display device of claim 1, further comprising:
a thin film transistor formed on the common electrode; and
a connection electrode connecting the thin film transistor and the pixel electrode.

3. The display device of claim 2, wherein:
the pixel electrode is formed to cover an upper surface of the microcavity.

4. The display device of claim 3, wherein:
the pixel electrode is formed not to cover a side surface of the microcavity.

5. The display device of claim 4, wherein:
the microcavity is not positioned on the thin film transistor, and
the connection electrode is formed to pass through a part of the side surface of the microcavity.

6. The display device of claim 2, wherein:
the substrate includes a plurality of pixel areas,
the common electrode is formed on the entire surface of the substrate, and
the pixel electrode is formed in the pixel area.

7. The display device of claim 6, wherein:
the pixel electrode includes a horizontal stem and a vertical stem crossing each other, and a minute branch extending from the horizontal stem and the vertical stem.

8. The display device of claim 7, further comprising:
a gate line and a data line formed on the common electrode,
wherein the gate line and the data line are connected with the thin film transistor.

9. The display device of claim 8, wherein:
the common electrode includes openings formed at portions overlapping with the gate line and the data line.

10. The display device of claim 6, further comprising:
a color filter formed below the common electrode,
wherein the color filter is formed in the pixel area.

11. A manufacturing method of a display device, comprising:
forming a common electrode on a substrate;
forming a sacrificial layer on the common electrode;
forming a pixel electrode on the sacrificial layer;
forming a roof layer on the pixel electrode;
forming an injection hole by patterning the roof layer so that a part of the sacrificial layer is exposed;
forming a microcavity between the common electrode and the pixel electrode by removing the sacrificial layer;
forming a liquid crystal layer in the microcavity by injecting a liquid crystal material through the injection hole; and
forming an encapsulation layer on the roof layer to seal the microcavity.

12. The manufacturing method of a display device of claim 11, further comprising:
forming a thin film transistor on the common electrode.

13. The manufacturing method of a display device of claim 12, wherein:
in the forming of the pixel electrode,
a connection electrode connecting the thin film transistor and the pixel electrode is further formed.

14. The manufacturing method of a display device of claim 13, wherein:
the pixel electrode is formed to cover an upper surface of the sacrificial layer and not to cover a side surface of the sacrificial layer.

15. The manufacturing method of a display device of claim 14, wherein:
the connection electrode is formed to pass through a part of the side surface of the sacrificial layer.

16. The manufacturing method of a display device of claim 12, wherein:
the substrate includes a plurality of pixel areas,
the common electrode is formed on the entire surface of the substrate, and
the pixel electrode is formed in the pixel area.

17. The manufacturing method of a display device of claim 16, wherein:
a horizontal stem and a vertical stem crossing each other, and a minute branch extending from the horizontal stem and the vertical stem are formed by patterning the pixel electrode.

18. The manufacturing method of a display device of claim 17, wherein:
the forming of the thin film transistor includes:
forming a gate line connected to the thin film transistor; and
forming a data line connected with the thin film transistor.

19. The manufacturing method of a display device of claim 18, further comprising:
forming openings by patterning the common electrode to remove at least a part of the portions overlapping with the gate line and the data line.

20. The manufacturing method of a display device of claim 16, further comprising:
forming a color filter in the pixel area on the substrate,
wherein the color filter is positioned below the common electrode.
